(19) United States
(12) Patent Application Publication
(10) Pub. No.: US 2026/0239685 A1
(43) Pub. Date: Aug. 13, 2026

(54) AIR GAP FORMATION IN GATE ISOLATION FEATURES

(71) Applicant: Taiwan Semiconductor Manufacturing Company, Ltd., Hsin-Chu (TW)

(72) Inventors: Ping-En Cheng, Hsinchu (TW); Yung-Ting Chang, New Taipei City (TW); Jui-Lin Chen, Taipei City (TW); Shih-Hao Lin, Hsinchu (TW)

(21) Appl. No.: 19/053,147

(22) Filed: Feb. 13, 2025

(51) Int. Cl. H10D 62/10; H10D 30/01; H10D 30/43; H10D 30/62; H10D 30/67; H10D 64/01; H10D 84/01

(52) U.S. Cl. CPC H10D 62/115; H10D 30/014; H10D 30/024; H10D 30/43; H10D 30/6735; H10D 30/6757; H10D 84/0151; H10D 30/6211; H10D 62/121; H10D 64/017; H10D 64/021; H10D 84/0147

(57) ABSTRACT

A method of forming a semiconductor device includes etching through a metal gate structure to form a trench between a first and a second active region; depositing a barrier layer in the trench, the barrier layer conforms to and partially fills the trench; depositing a sacrificial layer over the barrier layer to fully fill the trench; planarizing top surfaces of the barrier layer and the sacrificial layer to form a gate isolation feature having the barrier layer and the sacrificial layer; thinning down the substrate and the gate isolation feature from a backside to form an opening in the barrier layer; removing the sacrificial layer through the opening to form a modified gate isolation feature, the modified gate isolation feature having an air gap between portions of the barrier layer; and forming a capping layer on the backside of the modified gate isolation feature to seal the air gap.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

As technology nodes become smaller, unintended coupling between adjacent transistor components may lead to capacitance degradation, current leakage, and performance loss. The unwanted coupling may be between semiconductor active regions, between metal gates, and/or between various metal lines. To address this, various isolation structures may be formed for proper electrical isolation. For example, gate isolation features, also referred to as gate cut features or cut-metal-gate (CMG) features, may be formed to isolate gates between adjacent transistor devices. However, for advanced nodes that have very small separation between gates, the gate isolation features still produces high capacitive coupling. Further, the gate isolation features may cause metal gate oxidation that adversely impacts threshold voltage uniformity.

Therefore, although existing methods of forming gate isolation features have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates a flow chart of a method to form a semiconductor device, in portion or in entirety, according to an embodiment of the present disclosure.

FIG. 2 illustrates a three-dimensional view of a semiconductor workpiece with lines A-A′, B-B′, and C-C′ cut across the workpiece, according to an embodiment of the present disclosure.

FIGS. 3A, 4A, 5A, 6A, 7A, 8A, 9A, and 10A illustrate cross-sectional views of a semiconductor device cut along the lines A-A′ in FIG. 2 at intermediate stages of fabrication and processed in accordance with the method of FIG. 1, according to an embodiment of the present disclosure.

FIGS. 3B, 4B, 5B, 6B, 7B, 8B, 9B, and 10B illustrate cross-sectional views of a semiconductor device cut along the lines B-B′ in FIG. 2 at intermediate stages of fabrication and processed in accordance with the method of FIG. 1, according to an embodiment of the present disclosure.

FIGS. 3C, 4C, 5C, 6C, 7C, 8C, 9C, and 10C illustrate cross-sectional views of a semiconductor device cut along the lines C-C′ in FIG. 2 at intermediate stages of fabrication and processed in accordance with the method of FIG. 1, according to an embodiment of the present disclosure.

FIG. 11 illustrates a flow chart of a method to form a semiconductor device having a gate isolation feature with an embedded air gap, in portion or in entirety, according to an embodiment of the present disclosure.

FIGS. 12-22 illustrate cross-sectional views of a semiconductor device at intermediate stages of fabrication and processed in accordance with the method of FIG. 11 according to an embodiment of the present disclosure.

FIG. 23 illustrates various dimensions of a semiconductor device having a gate isolation feature with an embedded air gap, according to an embodiment of the present disclosure.

FIG. 24 illustrates a graph showing optimal ratios related to a gate isolation feature and an air gap therewithin, according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself limit the relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, may be understood to be within +/−10% between the compared features. Further, disclosed dimensions of the different features can implicitly disclose dimension ratios between the different features.

To improve gate isolation between adjacent transistors, there is a need to reduce capacitive coupling while maintaining or improving transistor performance. Gate isolation structures often cause high capacitive coupling due to its high dielectric constant and the closeness between adjacent transistor gates. Further, even if the gate isolation structures use low-k dielectric materials, there is risk of oxygen diffusion from the low-k dielectric materials into adjacent gates, causing the metal gates to oxidate. Metal gate oxidation leads to poorer transistor performance due to degrading threshold voltage (Vₜ) uniformity. To address these and other issues, the present disclosure describes forming a semiconductor device having a gate isolation feature with an embedded air gap. By incorporating an air gap in the gate isolation feature, the effective dielectric constant can be reduced, lowering capacitance. Further, barrier liners are used to prevent oxygen diffusion into the metal gates, thereby improving transistor performance by ensuring threshold voltage uniformity. As such, the gate isolation feature includes dual features: (1) a barrier layer to prevent oxidation and (2) an air gap between portions of the barrier layer to reduce gate-to-gate capacitance.

To illustrate the various aspects of the present disclosure, methods of forming a semiconductor device are discussed below. Embodiments shown in the present disclosure are implemented with Gate-All-Around (GAA) field effect transistors (FETs), but the present disclosure is not limited thereto. GAA FETs refer to transistors having gate stacks (gate electrodes and gate dielectric layers) surrounding transistor channels, such as vertically-stacked gate-all-around horizontal nanowire or nanosheet MOSFET devices. Those of ordinary skill in the art should appreciate that they may readily use the present disclosure as a basis for designing or modifying other structures for carrying out the same purposes and/or achieving the same advantages of the embodiments introduced herein. For example, the embodiments herein may also be implemented with planar MOSFETs, FinFETs, Forksheet FETs, complementary FETs (CFETs), and/or combinations thereof.

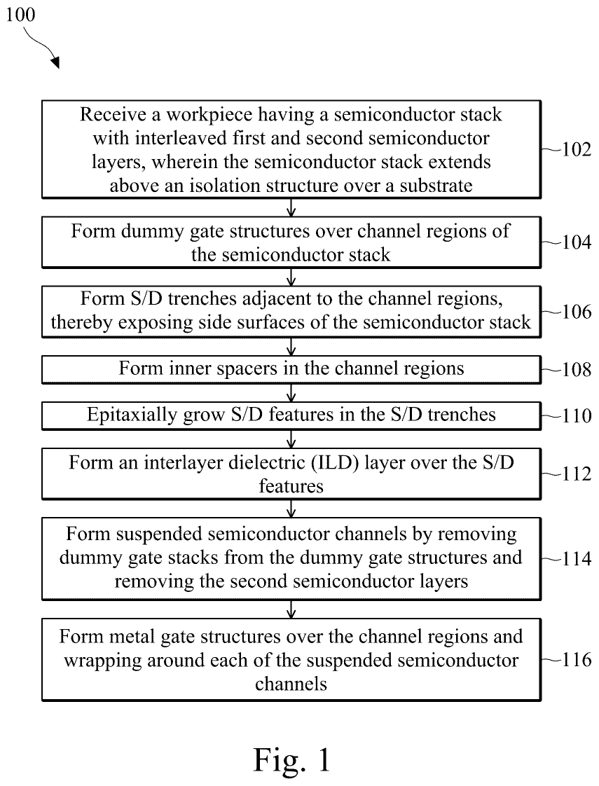

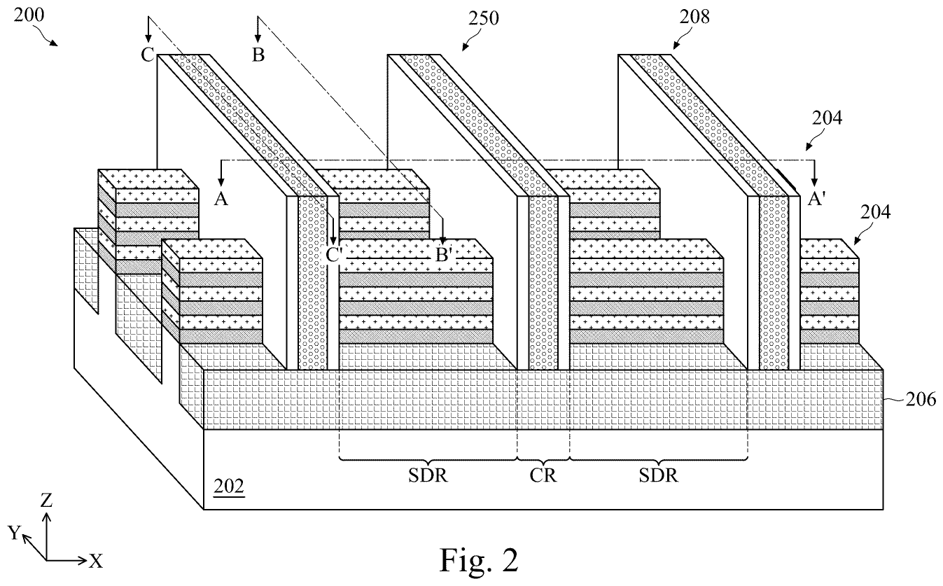

FIG. 1 illustrates a flow chart of a method 100 to form a semiconductor device 200, in portion or in entirety, according to an embodiment of the present disclosure. The method 100 is described below with reference to FIGS. 2, 3A-3C, 4A-4C, 5A-5C, 6A-6C, 7A-7C, 8A-8C, 9A-9C, and 10A-10C. These figures have been simplified for the sake of clarity to better understand the inventive concepts of the present disclosure. Additional features can be added in the semiconductor device 200, and some of the features described below can be replaced, modified, or eliminated in other embodiments of the semiconductor device 200.

Referring now to FIG. 2, the method 100 at operation 102 receives a semiconductor workpiece 250. The semiconductor workpiece 250 may correspond to a semiconductor device 200 at an initial or intermediate stage of fabrication. The semiconductor device 200 may be a portion of an integrated circuit (IC) chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, the device is included in a non-volatile memory, such as a non-volatile random access memory (NVRAM), a flash memory, an electrically erasable programmable read only memory (EEPROM), an electrically programmable read-only memory (EPROM), other suitable memory type, or combinations thereof.

FIG. 2 illustrates a three-dimensional view of the semiconductor workpiece 250 with lines A-A′, B-B′, and C-C′ cutting across a semiconductor device 200 at an initial or intermediate stage of fabrication. The workpiece 250 may include a substrate 202 and one or more semiconductor stacks 204 protruding from the substrate 202. The semiconductor stacks 204 protrude above an isolation structure 206 disposed over the substrate 202. The isolation structure 206 provides isolation between adjacent semiconductor stacks 204 and may be a shallow trench isolation (STI) layer. At operation 104, the method 100 forms dummy gate structures 208 over channel regions CR of the semiconductor stacks 204. The channel regions are defined by portions of the semiconductor stack 204 underneath the dummy gate structures 208. Adjacent to the channel regions are source drain regions SDR of the semiconductor stack 204. The semiconductor stacks 204 extend lengthwise in the x direction, and the dummy gate structures 208 extend lengthwise in the y direction. Note that forming dummy gate structures 208 is a separate step from forming semiconductor stacks 204. But for the sake of brevity, FIG. 2 shows the received workpiece 250 already having dummy gate structures 208 formed.

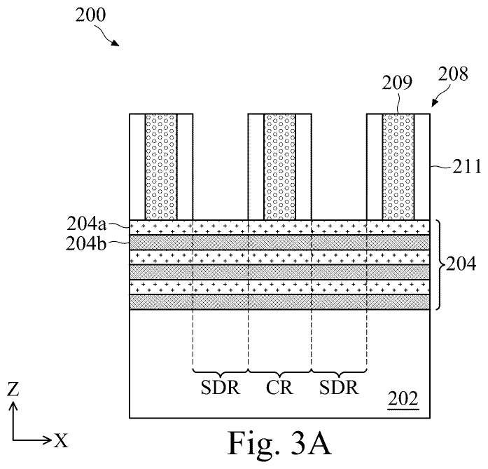

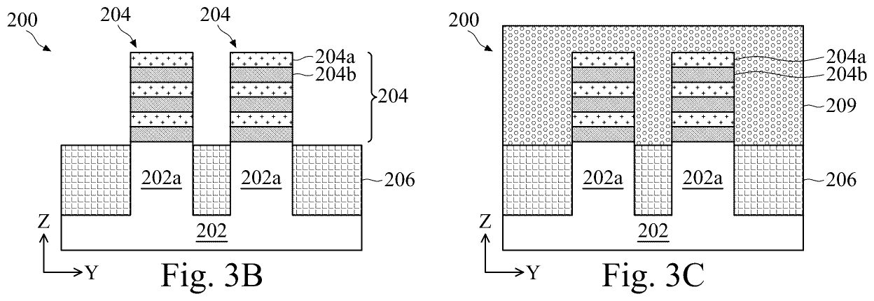

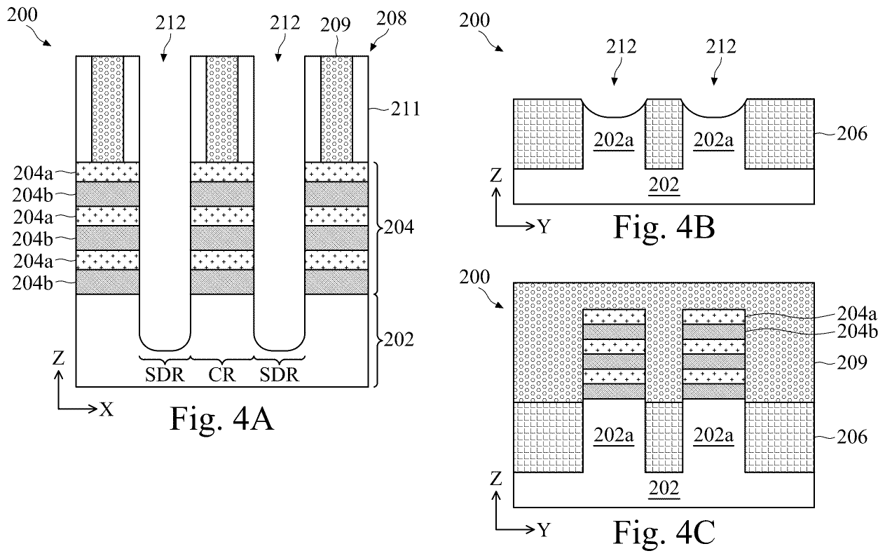

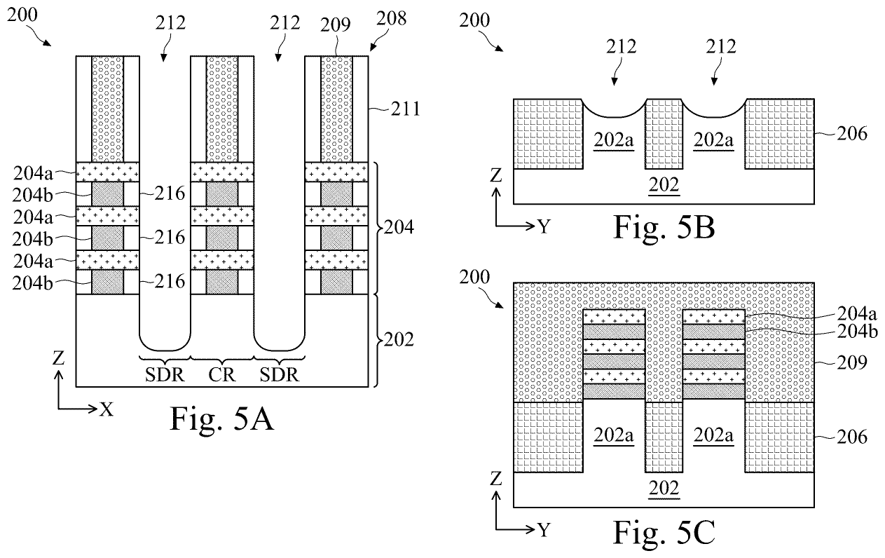

As shown in FIG. 2, the A-A′ line cuts along a semiconductor stack 204 in the x direction (lengthwise direction of the semiconductor stacks 204) and across several dummy gate structures 208. The B-B′ line cuts across source drain regions SDR of semiconductor stacks 204 in the y direction (lengthwise direction of the dummy gate structures 208) and across portions of the isolation structure 206 surrounding the semiconductor stacks 204. The C-C′ line cuts across a dummy gate structure 208 in the y direction (lengthwise direction of the dummy gate structures 208) and across several semiconductor stacks 204. FIGS. 3A, 4A, 5A, 6A, 7A, 8A, 9A, and 10A illustrate cross-sectional views of the semiconductor workpiece 250 cut along the lines A-A′ and processed in accordance with the method 100 of FIG. 1. FIGS. 3B, 4B, 5B, 6B, 7B, 8B, 9B, and 10B illustrate cross-sectional views of the semiconductor workpiece 250 cut along the lines B-B′ and processed in accordance with the method 100 of FIG. 1. FIGS. 3C, 4C, 5C, 6C, 7C, 8C, 9C, and 10C illustrate cross-sectional views of the semiconductor workpiece 250 cut along the lines C-C′ and processed in accordance with the method 100 of FIG. 1. FIGS. 2 and 3A-3C are at a same stage of fabrication, FIGS. 4A-4C are at a same stage of fabrication, FIGS. 5A-5C are at a same stage of fabrication, and so on and so forth.

Referring now to FIG. 2 and FIGS. 3A-3C collectively, one or more semiconductor stacks 204 are disposed over the substrate 202. The substrate 202 may be a silicon (Si) substrate, or a substrate having other semiconductor materials such as germanium (Ge), silicon carbide (SiC), silicon germanium (SiGe), or diamond. The semiconductor stacks 204 may also be referred to as semiconductor fins 204 or fin active regions 204. The semiconductor stacks 204 include interleaved first and second semiconductor layers 204a and 204b. The first semiconductor layers 204a have a different material composition than the second semiconductor layers 204b. For example, each of the first semiconductor layers 204a is made of silicon and each of the second semiconductor layers 204b is made of silicon germanium. The first semiconductor layers 204a may be of a same material composition as the substrate 202.

The dummy gate structures 208 are disposed over the channel regions CR of the semiconductor stacks 204. Each of the dummy gate structures 208 includes a dummy gate stack 209 and gate spacers 211 over sidewalls of the dummy gate stack 209. As shown in FIG. 3C, the dummy gate stack 209 lands on the isolation structure 206 and surrounds top and side surfaces of the semiconductor stacks 204. The dummy gate stack 209 may be made of polysilicon and the gate spacers 211 may be made of silicon oxide, silicon nitride, silicon oxycarbide, silicon oxycarbonitride, silicon carbonitride, metal nitride, or a suitable dielectric material. The source drain regions SDR extend between adjacent dummy gate structures 208.

Each of the semiconductor stacks 204 extends above the isolation structure 206 over the substrate 202. The substrate 202 may include protruding portions 202a that protrude above a top surface of the isolation structure 206. And the semiconductor stacks 204 may extend from top surfaces of the protruding portions 202a. As described herein, the protruding portions 202a may also be referred to as part of the semiconductor fins 204. Each of the protruding portions 202a are interposed by the isolation structure 206. As such, the isolation structure 206 interfaces with a top surface of the substrate 202 and side surfaces of the protruding portions 202a. The isolation structure 206, which may be a shallow trench isolation (STI) layer, provides isolation between adjacent semiconductor stacks 204. In an example process, a dielectric material for the isolation structure 206 is deposited over the workpiece 250 using CVD, subatmospheric CVD (SACVD), flowable CVD, physical vapor deposition (PVD), spin-on coating, and/or other suitable process. Then the deposited dielectric material is planarized and recessed until the semiconductor stacks 204 rises above the isolation structure 206. The dielectric material for the isolation structure 206 may include silicon oxide, silicon oxynitride, fluorine-doped silicate glass (FSG), a low-k dielectric, combinations thereof, and/or other suitable materials.

Referring now to FIGS. 4A-4C collectively, the method 100 at operation 106 forms S/D trenches 212 in the S/D regions SDR adjacent to the channel regions CR. The S/D trenches 212 expose side surfaces of remaining portions of the semiconductor stacks 204 (i.e., portions in the channel regions CR). The S/D trenches 212 may be formed by a dry etching process, a wet etching process, other suitable etching process, or combinations thereof. In some embodiments, the etching process is a multi-step etch process. For example, the etching process may include alternative etchants to separately and alternately remove semiconductor layers 204a and semiconductor layers 204b. In some embodiments, parameters of the etching process are configured to selectively etch semiconductor stacks 204 with minimal (to no) etching of dummy gate structures 208 (i.e., dummy gate stacks 209 and gate spacers 211). In some embodiments, a lithography process is performed to form a patterned mask layer that covers dummy gate structures 208, and the etching process uses the patterned mask layer as an etch mask when forming the S/D trenches 212.

Referring now to FIGS. 5A-5C collectively, the method 100 at operation 108 forms inner spacers 216 in the channel regions CR along sidewalls of the semiconductor layers 204b by any suitable process. For example, a side etch process may first be performed to selectively etch sidewalls of the second semiconductor layers 204b without etching (or substantially etching) the first semiconductor layers 204a. In other words, the side etch process is configured to laterally etch (e.g., along the x direction) semiconductor layers 204b, thereby reducing a length of semiconductor layers 204b along the x direction. The side etch process is a dry etching process, a wet etching process, other suitable etching process, or combinations thereof. After the side etch process is performed, air gaps are formed under each of the first semiconductor layers 204a. Then, inner spacers 216 are formed in each of the air gaps. The inner spacers 216 are disposed directly below the gate spacers 211, and they may be substantially vertically aligned with the gate spacers 211 along the z direction.

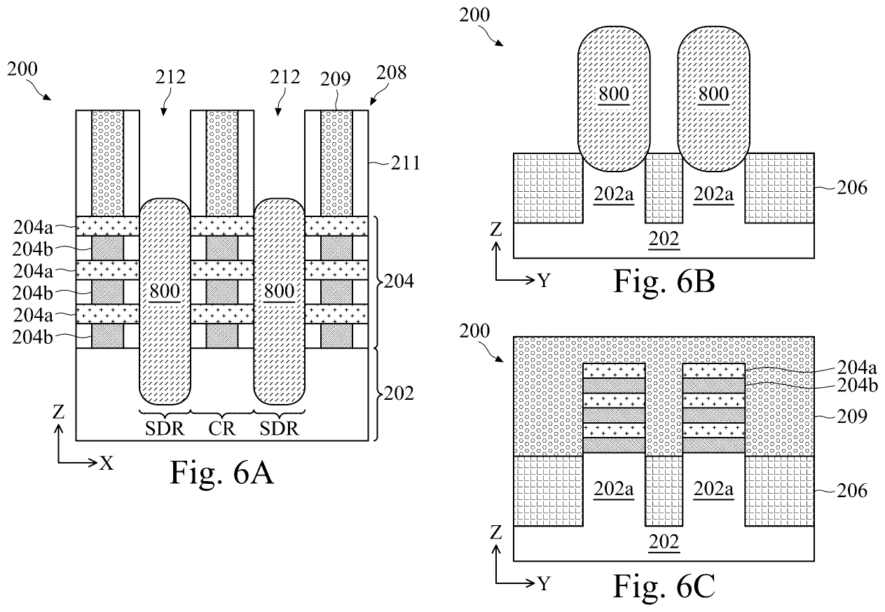

The inner spacers 216 may be formed by a spacer deposition process and a spacer etching process. For example, a spacer deposition process is performed to form a spacer layer over the dummy gate structures 208 and over features defining the S/D trenches 212 (e.g., semiconductor layers 204a, semiconductor layers 204b, and substrate 202 in FIG. 5A). The spacer deposition process may include processes such as CVD, PVD, ALD, HDPCVD, MOCVD, RPCVD, PECVD, LPCVD, ALCVD, APCVD, plating, other suitable methods, or combinations thereof. The spacer layer partially (and, in some embodiments, completely) fills the S/D trenches 212. The spacer deposition process is configured to ensure that the spacer layer fills the air gaps between semiconductor layers 204a and between semiconductor layers 204a and substrate 202 under gate spacers 211. A spacer etching process is then performed that selectively etches the spacer layer to form inner spacers 216 as depicted in FIG. 6A with minimal (to no) etching of semiconductor layers 204a, dummy gate stacks 209, and gate spacers 211. The spacer layer (and thus inner spacers 216) includes a material that is different than a material of semiconductor layers 204a and a material of gate spacers 211 to achieve desired etching selectivity during the gate spacer etching process. In some embodiments, the spacer layer includes a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the spacer layer includes a low-k dielectric material.

Referring now to FIGS. 6A-6C collectively, the method 100 at operation 110 epitaxially grows S/D features 800 in the S/D trenches 212 and over the protruding portions 202a of the semiconductor fins 204. The S/D features 800 may include n-type S/D features that correspond with n-type GAA transistor regions or p-type S/D features that correspond with p-type GAA transistor regions. The S/D features 800 may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of the substrate 202 (or protruding portion 202a thereof) and/or semiconductor stacks 204 (in particular, semiconductor layers 204a). Epitaxial S/D features 800 are doped with n-type dopants and/or p-type dopants. In some embodiments, for the n-type GAA transistors, epitaxial S/D features 800 include silicon and can be doped with carbon, phosphorous, arsenic, other n-type dopant, or combinations thereof (for example, forming Si:C epitaxial source/drain features, Si:P epitaxial source/drain features, or Si:C:P epitaxial source/drain features). In some embodiments, for the p-type GAA transistors, epitaxial S/D features 800 include silicon germanium or germanium and can be doped with boron, other p-type dopant, or combinations thereof (for example, forming Si:Ge:B epitaxial source/drain features).

In some embodiments, epitaxial S/D features 800 include materials and/or dopants that achieve desired tensile stress and/or compressive stress in respective channel regions CR. In some embodiments, epitaxial S/D features 800 are doped during deposition by adding impurities to a source material of the epitaxy process (i.e., in-situ). In some embodiments, epitaxial S/D features 800 are doped by an ion implantation process subsequent to a deposition process. In some embodiments, annealing processes (e.g., rapid thermal annealing (RTA) and/or laser annealing) are performed to activate dopants in epitaxial S/D features 800 and/or other source/drain regions (for example, heavily doped source/drain regions and/or lightly doped source/drain (LDD) regions). In some embodiments, epitaxial S/D features 800 are formed in separate processing sequences that include, for example, masking p-type GAA transistor regions when forming epitaxial S/D features 800 in n-type GAA transistor regions and masking n-type GAA transistor regions when forming epitaxial S/D features 800 in p-type GAA transistor regions.

In some embodiments (not shown), epitaxial S/D features 800 are formed to include more than one epitaxial layer. For example, each of the S/D features 800 includes an inner heavily doped layer and an outer lightly doped layer (or layers). In one embodiment, the outer lightly doped layer is first epitaxially grown in the S/D trenches 212 from side surfaces of the semiconductor layers 204a and the substrate 202. Then, the inner heavily doped layer is epitaxially grown from the outer lightly doped layer to fill the S/D trenches 212. The S/D features 800 may grow to a height above the topmost first semiconductor layers 204a and between gate spacers 211 of different dummy gate structures 208.

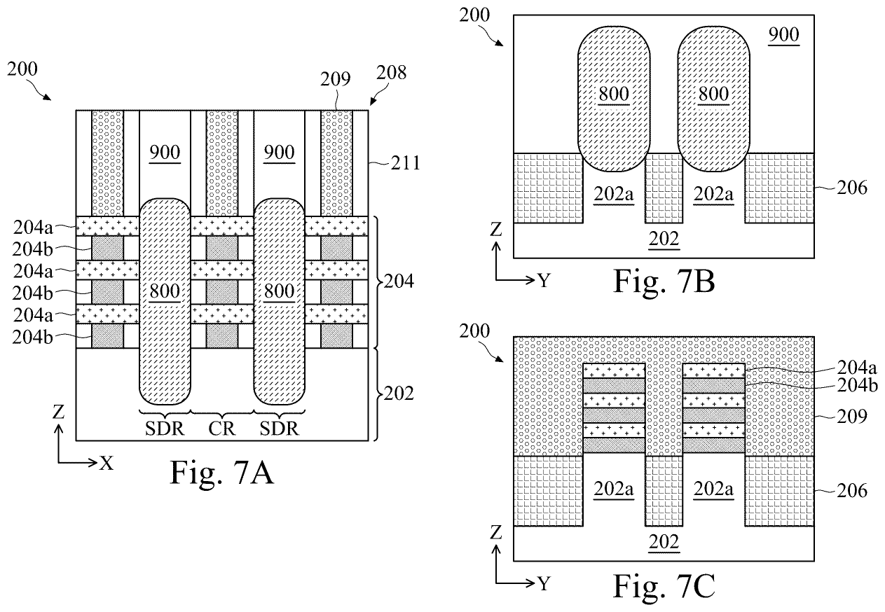

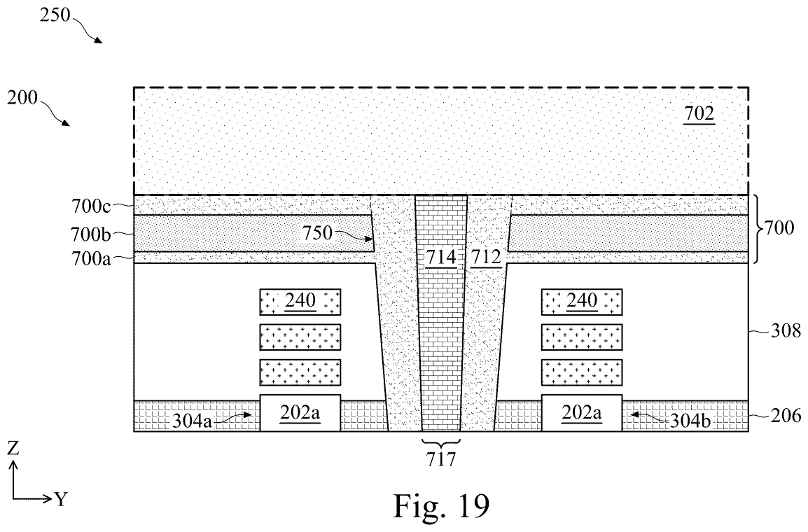

Referring now to FIGS. 7A-7C collectively, the method 100 at operation 112 forms an interlayer dielectric (ILD) layer 900 over the S/D features 800. As shown in FIG. 19A, the ILD layer 900 also fills the space between adjacent dummy gate structures 208. The ILD layer 900 may be formed by a deposition process (such as CVD, PVD, ALD, HDPCVD, MOCVD, RPCVD, PECVD, LPCVD, ALCVD, APCVD, plating, other suitable methods, or combinations thereof). In some embodiments, ILD layer 900 is formed by a flowable CVD (FCVD) process that includes, for example, depositing a flowable material (such as a liquid compound) over the device 200 and converting the flowable material to a solid material by a suitable technique, such as thermal annealing and/or ultraviolet radiation treating.

The ILD layer 900 includes a dielectric material including, for example, silicon oxide, silicon nitride, silicon oxynitride, TEOS formed oxide, PSG, BPSG, low-k dielectric material, other suitable dielectric material, or combinations thereof. Exemplary low-k dielectric materials include FSG, carbon doped silicon oxide, Black Diamond® (Applied Materials of Santa Clara, California), Xerogel, Aerogel, amorphous fluorinated carbon, Parylene, BCB, SiLK (Dow Chemical, Midland, Michigan), polyimide, other low-k dielectric material, or combinations thereof. In the depicted embodiment, ILD layer 900 is a dielectric layer that includes a low-k dielectric material (generally referred to as a low-k dielectric layer). ILD layer 900 can include a multilayer structure having multiple dielectric materials. In some embodiments, a contact etch-stop layer (CESL) (not shown) is disposed between ILD layer 900 and the S/D features 800, and between ILD layer 900 and the gate spacers 211. The CESL includes a material different than ILD layer 900, such as a dielectric material that is different than the dielectric material of ILD layer 900. For example, where ILD layer 900 includes silicon oxide or a low-k dielectric material, the CESL includes silicon and nitrogen, such as silicon nitride or silicon oxynitride. Subsequent to the deposition of ILD layer 900 and/or the CESL, a CMP process and/or other planarization process may be performed until reaching (exposing) a top portion (or top surface) of dummy gate stacks 209.

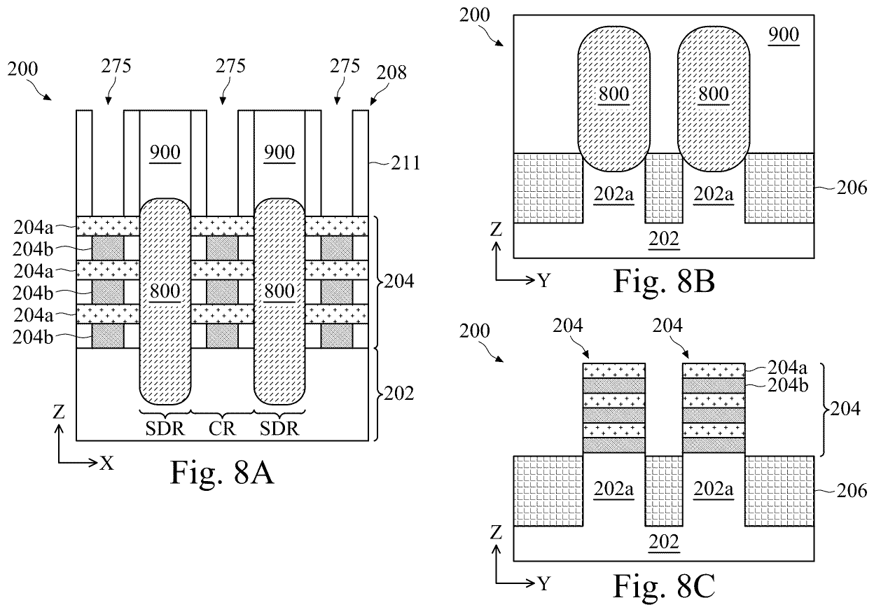

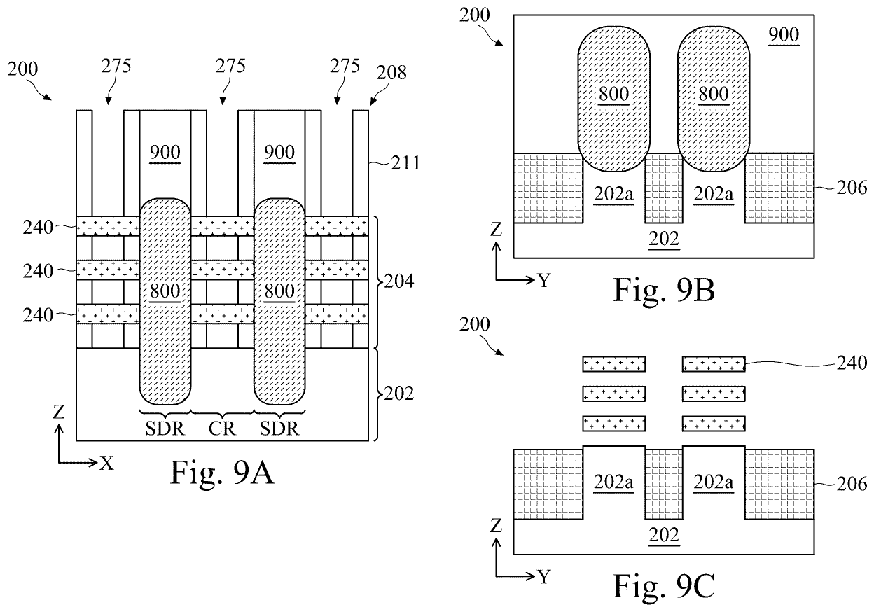

Referring now to FIGS. 8A-8C and 9A-9C collectively, the method 1000 at operation 114 forms suspended semiconductor channels 240 by removing dummy gate stacks 209 from the dummy gate structures 208 and removing the semiconductor layers 204b.

First, as shown in FIGS. 8A-8C, the operation 114 removes the dummy gate stacks 209 to expose the channel regions CR under the dummy gate stacks 209. The dummy gate stacks 209 are removed by a suitable etching process, thereby resulting in gate trenches 275 and exposing the semiconductor stacks 204. The etching process is designed with etchant to selectively remove the dummy gate stacks 209. In the depicted embodiment, an etching process completely removes dummy gate stacks 209 to expose surfaces of the semiconductor layers 204a and semiconductor layers 204b in the y-z plane (see FIG. 8C). The etching process is a dry etching process, a wet etching process, other suitable etching process, or combinations thereof. In some embodiments, the etching process is a multi-step etch process. For example, the etching process may include alternative etchants to separately remove various layers of dummy gate stacks 209, such as dummy gate electrode layers, dummy gate dielectric layers, and/or dummy hard mask layers. In some embodiments, the etching process is configured to selectively etch dummy gate stacks 209 with minimal (to no) etching of other features of the device 200, such as ILD layer 900, gate spacers 211, semiconductor layers 204a, and semiconductor layers 204b. In some embodiments, a lithography process is performed to form a patterned mask layer that covers ILD layer 900 and/or gate spacers 211, and the etching process uses the patterned mask layer as an etch mask.

Second, as shown in FIGS. 9A-9C, the semiconductor layers 204b (exposed by the gate trenches 275) are selectively removed from the channel regions CR, forming suspended semiconductor channels 240. In other words, what remains of the semiconductor layers 204a now become suspended semiconductor channels 240. This removal process is also known as channel-release, and this stage of the manufacturing process is referred to as the channel-release stage. In the depicted embodiment, an etching process selectively etches semiconductor layers 204b with minimal (to no) etching of semiconductor layers 204a and, in some embodiments, minimal (to no) etching of gate spacers 211 and/or inner spacers 216. Various etching parameters can be tuned to achieve selective etching of semiconductor layers 204b, such as etchant composition, etching temperature, etching solution concentration, etching time, etching pressure, source power, RF bias voltage, RF bias power, etchant flow rate, other suitable etching parameters, or combinations thereof. For example, an etchant is selected for the etching process that etches the material of semiconductor layers 204b (in the depicted embodiment, silicon germanium) at a higher rate than the material of semiconductor layers 204a (in the depicted embodiment, silicon) (i.e., the etchant has a high etch selectivity with respect to the material of semiconductor layers 204b). The etching process is a dry etching process, a wet etching process, other suitable etching process, or combinations thereof.

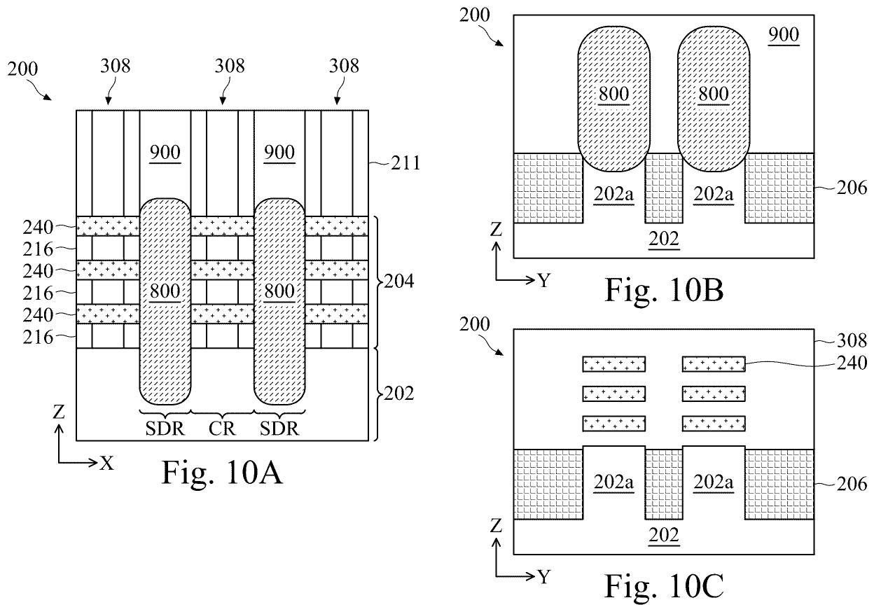

Referring now to FIGS. 10A-10C collectively, the method 1000 at operation 1016 forms metal gate structures 308 over the channel regions CR and wrapping around each of the suspended semiconductor channels 240. The metal gate structures 308 are deposited into the gate trenches 275 between the inner spacers 216 and the gate spacers 211. The metal gate structures 308 further lands on a top surface of the isolation structure 206. Although not shown, each of the metal gate structures 308 may include a gate dielectric layer and a gate electrode disposed on the gate dielectric layer. In some embodiments, the gate dielectric layer includes an interfacial layer and a high-k dielectric layer disposed on the interfacial layer. The gate electrode may include one or more conductive materials, such as a capping layer, a work function metal layer, a blocking layer, a metal fill layer, and/or other proper conductive material layers. The work function layers (if present) may be same or different and may be an n-type work function layer or a p-type work function layer, depending on the types of the corresponding GAA transistors. The gate dielectric layer includes a high-k dielectric material, such as materials having a dielectric constant greater than silicon oxide (k≈3.9). The gate electrodes may be formed by a CVD process or a PVD process that deposits a metal fill layer that fills remaining portions of the gate trenches 275 and over the gate dielectric layers. The metal fill layer includes a suitable conductive material, such as Al, W, and/or Cu. The metal fill layer may additionally or collectively include other metals, metal oxides, metal nitrides, other suitable materials, or combinations thereof. Alternatively, the metal fill layer is formed using another suitable deposition process, such as ALD, CVD, PVD, HDPCVD, MOCVD, RPCVD, PECVD, LPCVD, ALCVD, APCVD, spin coating, plating, other deposition process, or combinations thereof.

A planarization process is performed to remove excess gate materials from the semiconductor device 200. For example, a CMP process is performed until a top surface of the ILD layer 900 is reached (exposed) so that top surfaces of the metal gate structures 308 are substantially planar with a top surface of ILD layer 900 after the CMP process. Accordingly, the semiconductor device 200 now forms GAA transistors having metal gate structures 308 wrapping respective semiconductor channels 240 (now no longer suspended), where the metal gate structures 308 are disposed between respective semiconductor channels 240 along the z direction and between respective epitaxial S/D features 800 along the x direction. Further, the metal gate structures 308 are separated from the S/D features 800 by the gate spacers 211 and the inner spacers 216.

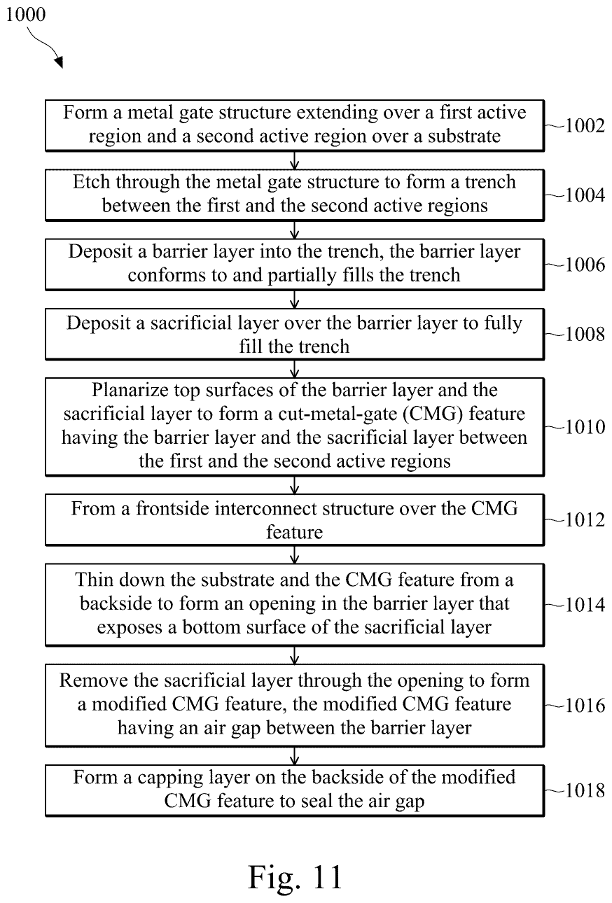

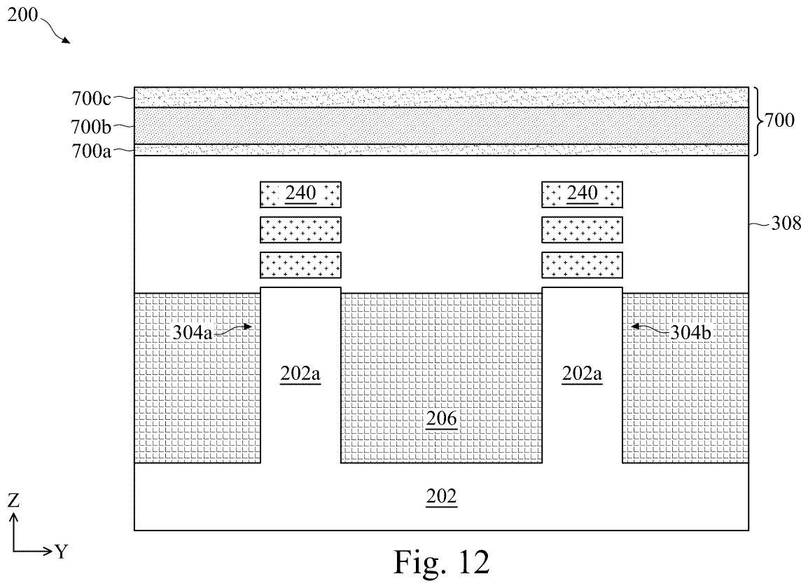

FIG. 11 illustrates a flow chart of a method 1000 to form a semiconductor device 200 having a gate isolation feature with an embedded air gap, in portion or in entirety, according to an embodiment of the present disclosure. In an embodiment, the semiconductor device 200 at the end of method 100 is received at the beginning of method 1000, and the received semiconductor device 200 continues to be processed according to the method 1000. For example, the method 100 at operation 116 may correspond to the method 1000 at operation 1002. The method 1000 is described below with reference to FIGS. 12-23. FIGS. 12-23 illustrate cross-sectional views of the semiconductor device 200 at intermediate stages of fabrication and processed in accordance with the method 1000 of FIG. 11. FIGS. 12-23 have been simplified for the sake of clarity to better understand the inventive concepts of the present disclosure. Additional features can be added in the semiconductor device 200, and some of the features described below can be replaced, modified, or eliminated in other embodiments of the semiconductor device 200. Further, the method 1000 may perform further steps to complete fabrication of the semiconductor device 200. Additional operations can be provided before, during, and after method 1000. Further, some of the operations described can be moved, replaced, or eliminated for additional embodiments of method 1000.

Referring now to FIG. 12, the method 1000 at operation 1002 forms a metal gate structure 308 over a first active region 304a and a second active region 304b over a substrate 202. Each of the first and the second active regions 304a and 304b include protruding portions 202a of the substrate 202 and semiconductor channels 240 disposed over the protruding portions 202a. The protruding portions 202a are base portions of the first and the second active regions 304a and 304b, and the protruding portions 202a are surrounded by an isolation structure 206. The metal gate structure 308 extends along the y direction and is disposed over channel regions of the first and the second active regions 304a and 304b. Various features of FIG. 12 have been previously described with respect to method 100, and the similar features are not described again for the sake of brevity.

Still referring to FIG. 12, the method 1000 at operation 1002 may perform further fabrication steps. For example, one or more dielectric layers 700 may be formed over the metal gate structure 308. Various device-level contacts (not shown) are formed through the one or more dielectric layers 700 to make electrical contact with underlying transistor devices (e.g., by landing on an S/D feature 800 and/or a gate structure 308 of the underlying transistor devices). In the embodiment shown, the one or more dielectric layers 700 may include a first etch stop layer 700a deposited on the metal gate structure 308, an ILD layer 700b deposited on the first etch stop layer 700a, and a second etch stop layer 700c deposited on the ILD layer 700b. The etch stop layers 700a and 700c may be contact etch stop layers having a different dielectric material than that of the ILD layer 700b. The etch stop layers 700a and 700c may include silicon nitride. The ILD layer 700b may include silicon oxide. In an embodiment, the ILD layer 700b include similar materials as the ILD layer 900 previously described. The various device-level contacts (not shown) may include gate contacts that penetrate through the one or more ILD layers 700 to land on the metal gate structure. The various device-level contacts (not shown) may further include S/D contacts that penetrate through the one or more ILD layers 700 and the ILD layer 900 previously described to land on the S/D features 800.

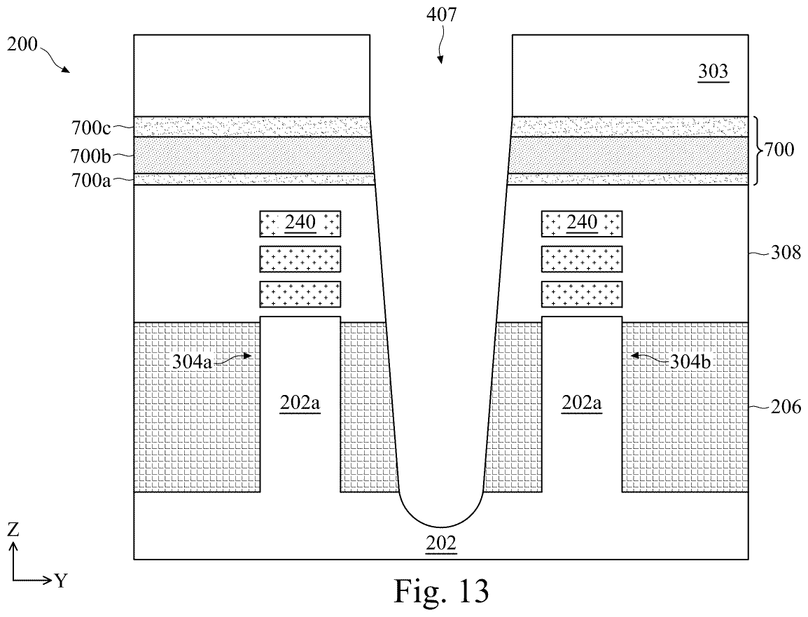

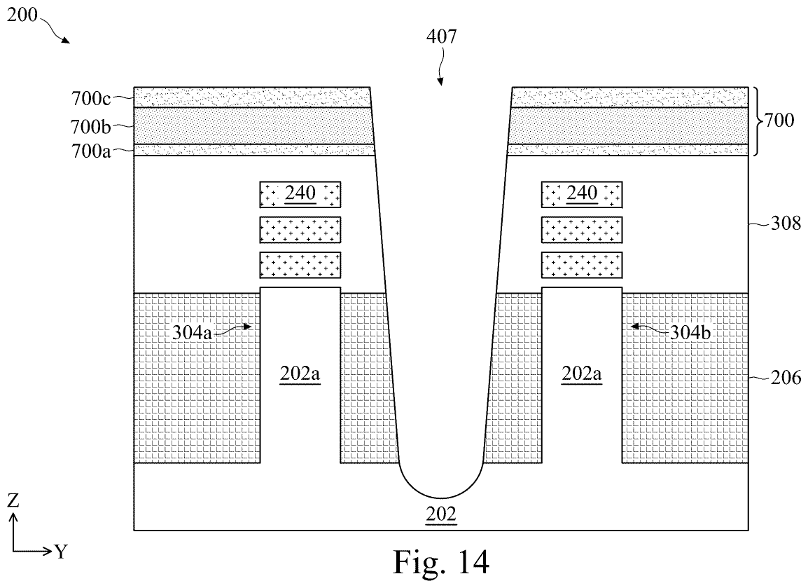

Referring now to FIGS. 13-14, the method 1000 at operation 1004 etches through the metal gate structure 308 to form a trench 407 between the first and the second active regions 304a and 304b. The trench 407 may be formed by a dry etching process, a wet etching process, other suitable etching process, or combinations thereof. In some embodiments, the etching process is a multi-step etch process. In some embodiments, operation 1004 includes a lithography process that forms a patterned mask layer 303. The patterned mask layer 303 exposes a region laterally between the first and the second active region 304a and 304b along the y direction. Thereafter, the etching process uses the patterned mask layer 303 as an etch mask when forming the trench 407.

In the embodiment shown, the operation 1004 etches through the one or more dielectric layers 700 and the metal gate structure 308. Further, to ensure that the gate structure 308 is fully cut, the operation 1004 at least partially etches through the isolation structure 206. Note that the etching process becomes less efficient at the bottom due to limited access for etch chemicals, thereby forming narrowing profiles. As such, the trench 407 may be etched deeper to ensure a wider trench in the y direction. A wider trench is preferable for improved capacitance reduction (i.e., more separation between gate metals), and further allows easier deposition of barrier liners into the trench 407. In the embodiment shown, the trench 407 is a deep trench that completely penetrates through the one or more dielectric layers 700, the metal gate structure 308, and the isolation structure 206. The trench 407 may expose a top surface of the substrate 202, such as by forming a dip into the substrate 202. After forming the trench 407, the patterned mask layer 303 is removed by any suitable process such as etching, ashing, stripping, and or a combination thereof.

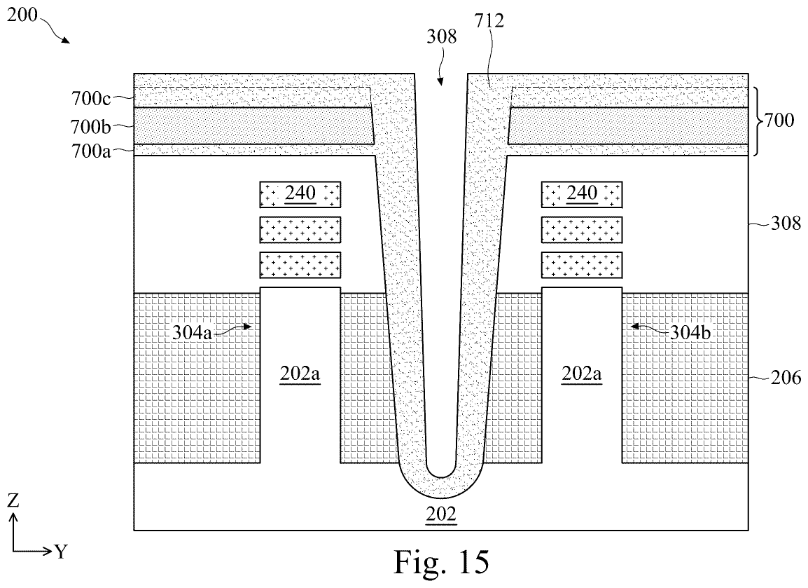

Referring now to FIG. 15, the method 1000 at operation 1006 deposits a barrier layer 712 into the trench 407, the barrier layer 712 conforms to and partially fills the trench 407. The barrier layer 712 further lands on a top surface of the one or more dielectric layers 700 (e.g., landing on the second etch stop layer 700c). The barrier layer 712 includes a nitride-based dielectric such as silicon nitride. In an embodiment, the barrier layer 712 has a same or similar material as the second etch stop layer 700c. In other embodiments, the barrier layer 712 includes a material different from that of the second etch stop layer 700c. For example, the barrier layer 712 includes a high-k dielectric comprising aluminum, zirconium, and/or titanium. Notably, the barrier layer 712 is chosen to act as a protective layer between electrodes, and to prevent metal gate oxidation. These types of material often exhibit high-k dielectric properties, which have the advantage of ensuring threshold voltage uniformity by preventing gate oxidation, but the disadvantage of increasing unwanted capacitive coupling. The present disclosure solves the capacitive coupling problem by lowering the effective dielectric constant between gates through a backside air gap, as further described herein.

In some embodiments, the barrier layer 712 includes silicon carbonitride. Silicon carbonitride is sometimes considered a low-k dielectric while being considered oxidation resistant. However, silicon carbonitride can still degrade at high temperatures when exposed to oxygen, leading to structural instability. This degradation can be exacerbated by the presence of carbon in the material. As such, silicon carbonitride may be used in combination with another high-k barrier layer. For example, the barrier layer 712 includes a silicon nitride layer (on side surfaces of the exposed metal gate structure 308) and a silicon carbonitride layer over sidewalls of the silicon nitride layer.

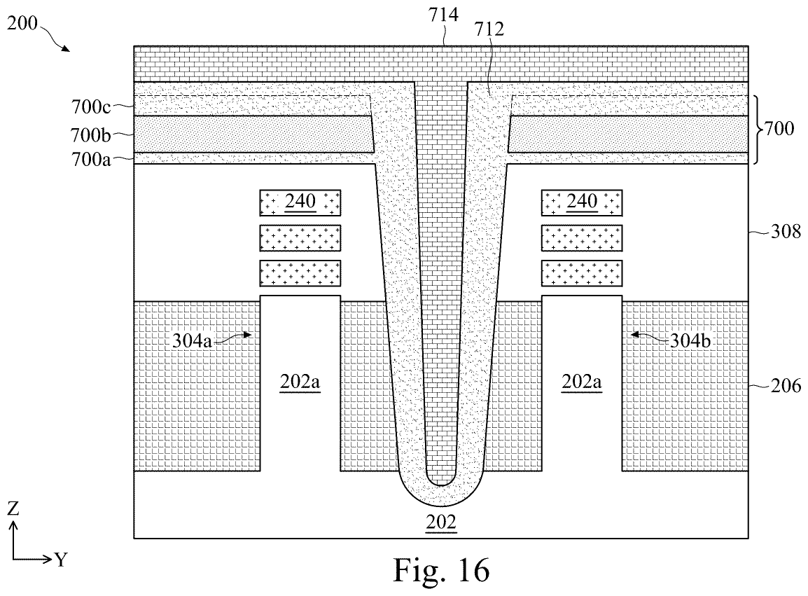

Referring now to FIG. 16, the method 1000 at operation 1008 deposits a sacrificial layer 714 over the barrier layer 712. The sacrificial layer 714 may be deposited in any suitable process, such as CVD, PVD, spin-on coating, and or combinations thereof. The sacrificial layer 714 fully fills the trench 407. The sacrificial layer 714 will be removed in a later process. As such, the sacrificial layer 714 includes a different material than that of the barrier layer 712 for etchant selectivity. For example, the barrier layer 712 includes silicon nitride, and the sacrificial layer 714 includes silicon oxide. Note however that the sacrificial layer 714 is not limited to silicon oxide. Since the sacrificial layer 714 will be removed, there is freedom to choose from a variety of materials. For example, to reduce risks of oxidation, the sacrificial layer 714 is chosen to have no or little oxygen (i.e., substantially free of oxygen). In an embodiment, the sacrificial layer 714 consists of silicon. In an embodiment, the sacrificial layer 714 includes a bottom anti-reflective coating (BARC) layer deposited via spin-on coating. The BARC layer may include silicon-containing polymers, carbon-containing polymers, or spin-on carbon (SOC).

The sacrificial layer 714 is deposited as a buffer layer for absorbing stress and providing structural support during back-end-of-line (BEOL) processes. Semiconductor fabrication may generally be divided into front-end-of-line (FEOL) and back-end-of-line (BEOL) processes. FEOL generally refers to circuit regions and related processes that includes everything from a substrate (e.g., silicon wafer) up to but not including metal interconnect layers. These regions may include the substrate, active regions, source/drain features of active regions, channel regions of active regions, gate, and device-level metal features (e.g., device-level contacts and vias). In some embodiments, the formation of device-level metal features is referred to as middle-of-line (MEOL) processes. The method 100 may be an example FEOL process that include MEOL processes. BEOL generally refers to circuit regions and related processes outside of the FEOL and MEOL. These regions may include metal interconnect layers (e.g., as part of an interconnect structure), backside of the substrate, or another wafer as part of a 3DIC structure.

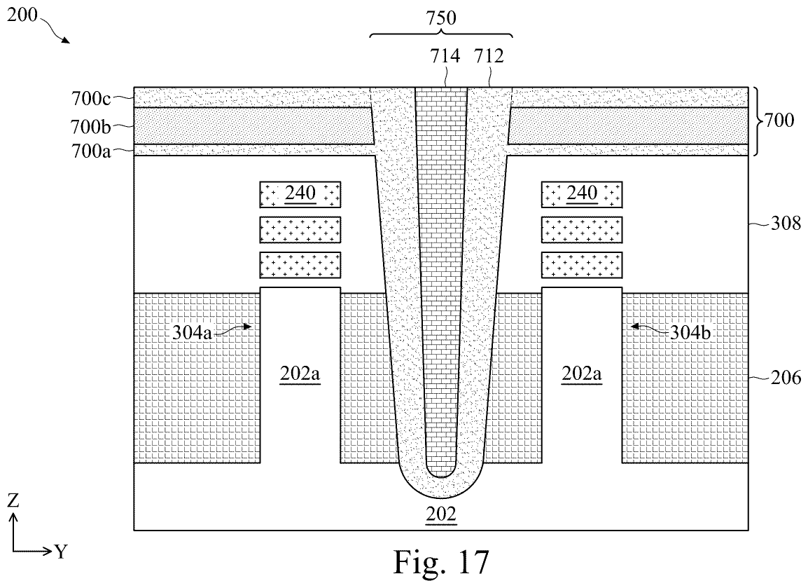

Referring now to FIG. 17, the operation 1010 performs a planarization process (e.g., chemical mechanical polish) to remove excess portions of the barrier layer 712 and the sacrificial layer 714 over the one or more dielectric layers 700. The resulting structure is a gate isolation feature 750 or a cut-metal-gate (CMG) feature 750 having the barrier layer 712 surrounding the sacrificial layer 714.

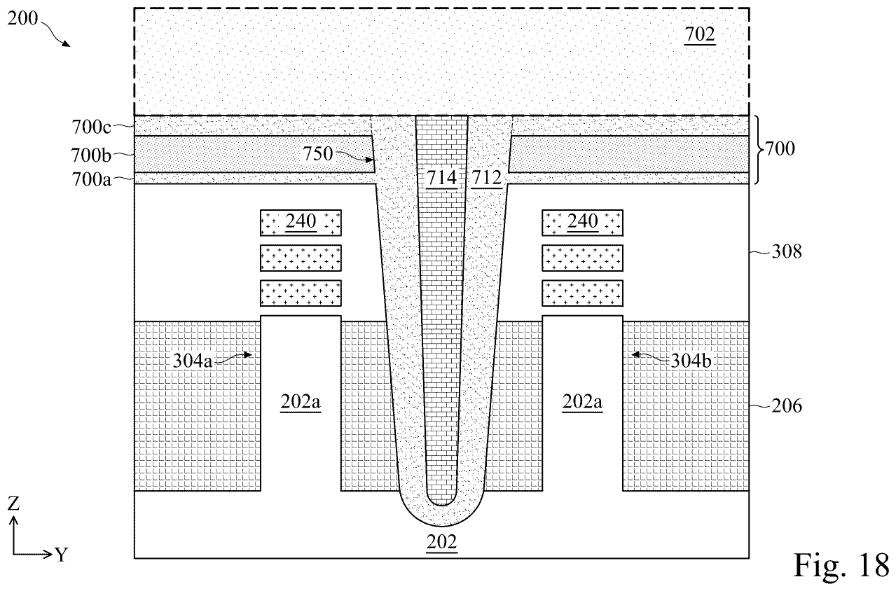

Referring now to FIG. 18, the method 1000 at operation 1012 forms a frontside interconnect structure 702 over the CMG feature 750 and over the one or more dielectric layers 700. The frontside interconnect structure 702 is formed as part of a BEOL process. For example, the one or more dielectric layers 700, the various device-level contacts in the one or more dielectric layers 700, and the CMG feature 750 are each formed as part of a FEOL process (or a MEOL process thereof). Thereafter, the BEOL process begins by forming the frontside interconnect structure 702 over the one or more dielectric layers 700, the various device-level contacts, and the CMG feature 750. The frontside interconnect structure 702 includes features that electrically couple various devices (for example, p-type GAA transistors and/or n-type GAA transistors of the device 200, transistors, resistors, capacitors, and/or inductors) and/or components (for example, gate structures and/or epitaxial source/drain features of p-type GAA transistors and/or n-type GAA transistors), such that the various devices and/or components can operate as specified by design requirements of the device 200. The frontside interconnect structure 702 includes a combination of dielectric layers and electrically conductive layers (e.g., metal layers) configured to form various interconnect layers. The conductive layers are configured to form vertical interconnect features, such as vias, and/or horizontal interconnect features, such as conductive lines. Vertical interconnect features typically connect horizontal interconnect features in different layers (or different planes) of the frontside interconnect structure 702. The various horizontal and vertical interconnect feature may land on the device-level contacts (not shown) formed in the one or more dielectric layers 700. During operation, the frontside interconnect structure 702 is configured to route signals between the devices and/or the components of the device 200 and/or distribute signals (for example, clock signals, voltage signals, and/or ground signals) to the devices and/or the components of the device 200.

Referring now to FIG. 19, the method 1000 at operation 1014 thins down the substrate 202 and the CMG feature 750 from a backside to form an opening 717 in the barrier layer 712 that exposes a bottom surface of the sacrificial layer 714. As shown, the thinning down includes completely removing the substrate 202 and further thinning down the isolation structure 206 surrounding the protruding portions 202a of the respective active regions 304a and 304b. The operation 1012 may include flipping the semiconductor workpiece 250 and performing a back side CMP. The removal of the substrate 202 improves device isolation by removing semiconductor connection between the first and the second active regions 304b. The thinning down also helps with the process window of removing the sacrificial layer 714. This is because after the thinning down, the CMG feature 750 has a shallow depth height. Specifically, the shallow depth height lowers the aspect ratio of the sacrificial layer 714 such that the sacrificial layer 714 can be easily removed.

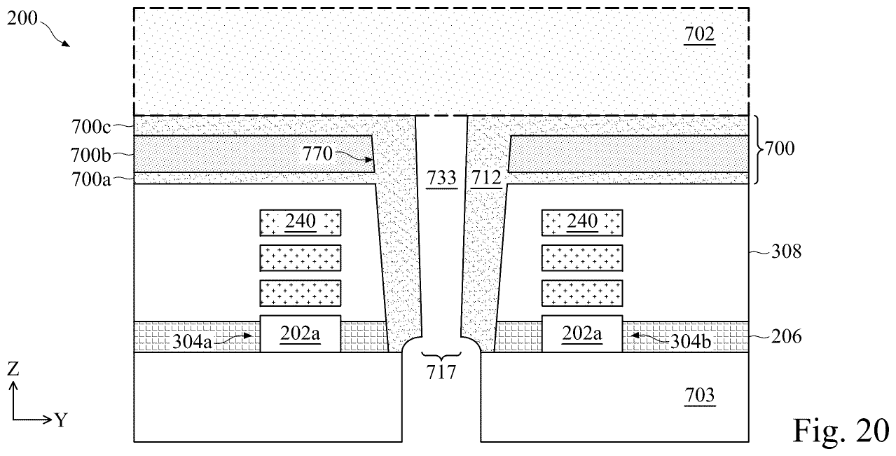

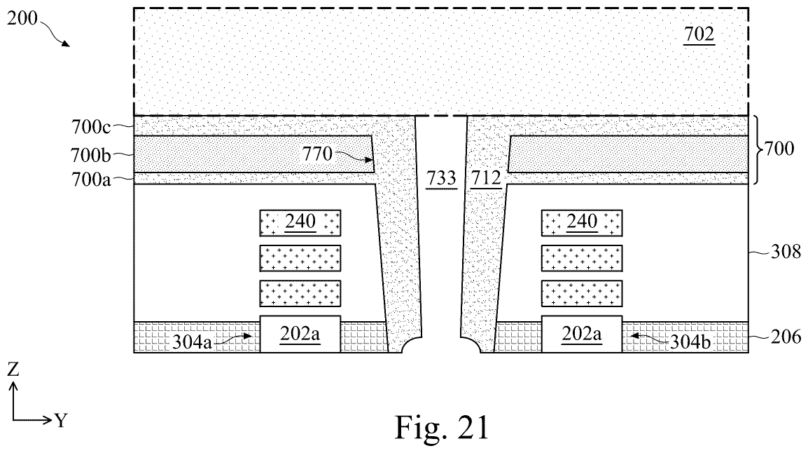

Referring now to FIG. 20, the method 1000 at operation 1016 removes the sacrificial layer 714 through the opening 717 to form a modified CMG feature 770, the modified CMG feature 770 having an air gap 733 between the barrier layer 712 (or portions thereof). The operation 1016 includes forming a backside hard mask 703. The backside hard mask 703 exposes a backside of the modified CMG feature 770 (including the barrier layer 712 and the sacrificial layer 714) while covering the backside of the isolation structure 206 and the protruding portions 202a. The backside hard mask 703 may be formed through a lithography process that includes patterning the hard mask 703 through a patterned photoresist. After the patterning, the patterned photoresist is stripped, leaving behind a patterned hard mask 703. The exposed sacrificial layer 714 is then etched away through the patterned hard mask 703, thereby forming the air gap 733. The air gap 733 may be formed by a dry etching process, a wet etching process, other suitable etching process, or combinations thereof. In an embodiment, the etching process includes applying an etchant that selectively etches sacrificial layer 714 at a faster rate than the barrier layer 712. The removing of the sacrificial layer 714 may alternatively (or additionally) include performing a plasma ashing or a wet stripping process (e.g., for removing BARC materials). Due to the reduced height of the modified CMG feature 770, the sacrificial layer 714 can be more easily etched/stripped away, leaving behind the air gap 733. In some embodiments, to ensure complete removal of the sacrificial layer 714 a stronger etchant and/or a longer etching time is applied. As such, bottom portions of the barrier layer 712 may also be partially etched. Referring now to FIG. 21, after removal of the sacrificial layer 714, the backside hard mask 703 may be removed by any suitable process such as etching, ashing, stripping, and or a combination thereof.

As shown in FIGS. 20-21, the air gap 733 is an air wall that separates remaining portions of the barrier layer 712. The remaining portions of the barrier layer 712 include disconnected barrier liners that line sidewalls of the cut metal gate, the one or more dielectric layers 700, and the isolation structure 206. Since air has the lowest possible dielectric constant of 1, the air wall provides a low-dielectric separation between the higher-k barrier liners, thereby helping to reduce capacitive coupling between separated gates. Meanwhile, the higher-k barrier liners provide the needed protection against oxygen diffusion to maintain device integrity.

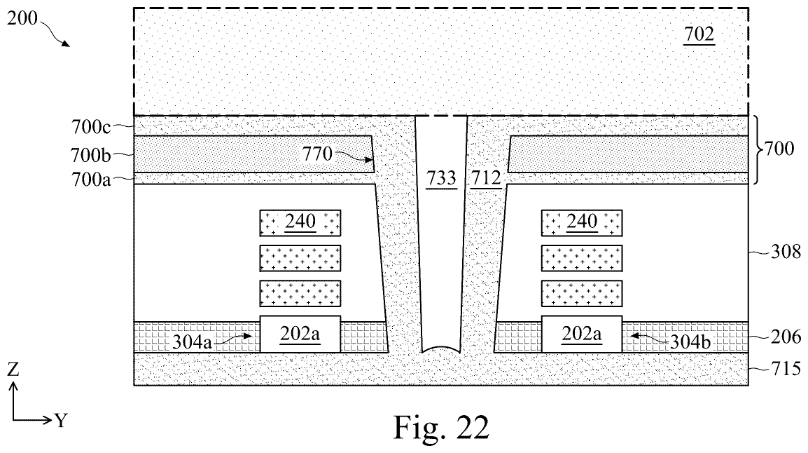

Referring now to FIG. 22, the method 1000 at operation 1018 forms a capping layer 715 on the backside of the modified CMG feature 770. The capping layer 715 is deposited to seal the air gap 733. The capping layer 715 may be deposited through any suitable method. As shown, due to the presence of the air gap 733, the capping layer 715 may have a portion that dips into the opening of the air gap 733. In an embodiment, the capping layer 715 is a silicon nitride hard mask. In an embodiment, the capping layer 715 includes a same or similar material as the barrier layer 712. In an embodiment, the capping layer 715 is a back side etch stop layer, and a backside interconnect structure (not shown) is formed on the backside etch stop layer. The backside interconnect structure may include various interconnect features similar to those described with respect to the frontside interconnect structure 702.

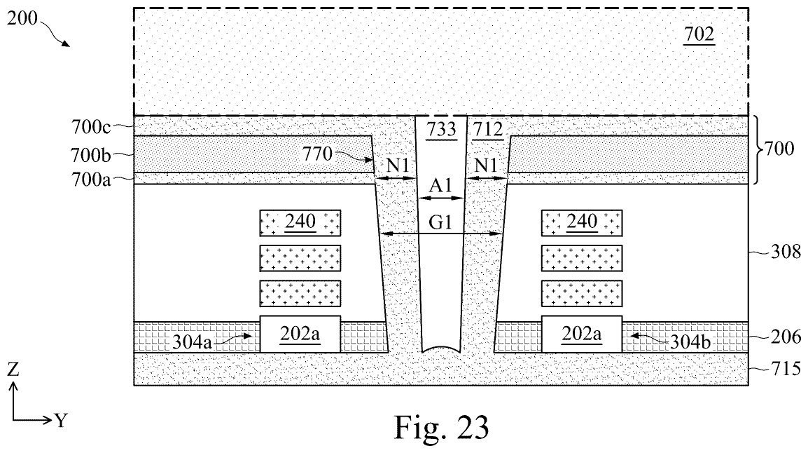

FIG. 23 illustrates various dimensions of a semiconductor device 200 having a gate isolation feature 770 (also referred herein as a modified CMG feature 770) with an embedded air gap 733, according to an embodiment of the present disclosure. As shown and described with respect to method 1000, the gate isolation feature 770 cuts through the metal gate structure 308 to isolate the gate of the first active region 304a from the gate of the second active region 304b. The first and second active regions 304a and 304b include semiconductor channels 240 wrapped around by the respective separated gates. As shown, the gate isolation feature 770 may further cut through one or more dielectric layers 700 that embed one or more device-level contacts (not shown). The gate isolation feature 770 further cuts through the isolation structure 206. The gate isolation feature 770 includes barrier liners (i.e., portions or segments of the barrier layer 712) interfacing side surfaces of the metal gates. The barrier liners are exposed in the air gap 733. The air gap 733 is defined by exposed surfaces of the interconnect structure 702, the barrier liners, and the capping layer 715. The air gap 733 is sealed by the capping layer 715 under and on bottom surfaces of the isolation structure 206, the active regions 304a and 304b, and the gate isolation feature 770.

Still referring to FIG. 23, the gate isolation feature 770 utilizes the barrier liners of the barrier layer 712 to prevent metal gate oxidation and threshold voltage degradation. The gate isolation feature 770 further utilizes the air gap 733 for gate-end to gate-end capacitive coupling reduction. However, to balance between threshold voltage performance and low effective capacitance, setting the various dimensions of the gate isolation feature 770 is not trivial. As shown along the y direction, the gate isolation feature 770 has a width G1, the air gap 733 has a width A1, and the barrier layer 712 has a width N1 defined as a difference between the width G1 and the width A1. If the width N1 is too big, the air gap A1 becomes too small, resulting in higher-than-desired effective capacitance coupling. On the other hand, if the width N1 is too small, the barrier liners of the barrier layer 712 becomes too thin, risking oxygen diffusion from the air gap 733 through the barrier liners and into the metal gates.

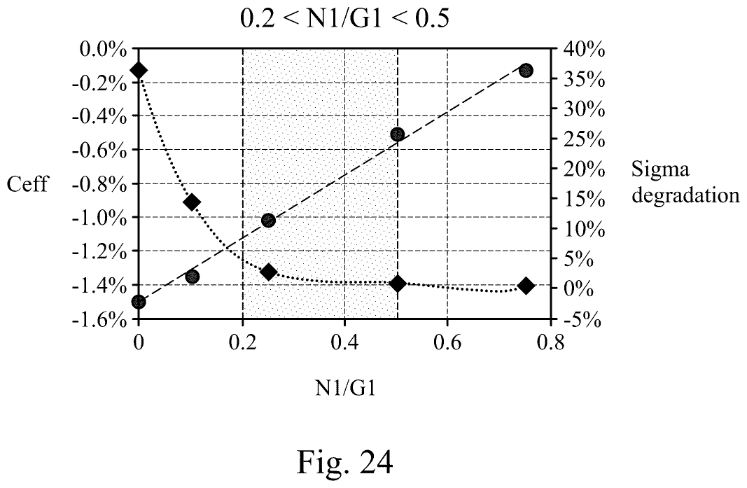

FIG. 24 illustrates a graph showing optimal ratios related to a gate isolation feature 770 and an air gap 733 therewithin, according to an embodiment of the present disclosure. FIG. 24 is described with reference to FIG. 23. Referring to the graph, as the ratio of the width N1 to the width G1 increases (i.e., thick barrier liners, small air gap), the effective capacitance has almost no capacitance reduction (e.g., achieving only 0.1% reduction), but the sigma degradation (referring to threshold voltage variation) is reduced to almost 0%. Meanwhile, as the ratio of the width N1 to the width G1 decreases (i.e., thin barrier liners, big air gap), the effective capacitance is increasingly reduced to almost −1.6%, but the sigma degradation (referring to threshold voltage variation) degrades up to almost 40%. In an embodiment, to balance both extremes, the ratio of the width N1 to width G1 is selected to between about 0.2 to about 0.5 (i.e., 0.2<N1/G1<0.5). In this way, the effective capacitance has at least 0.5% reduction but less than 5% sigma degradation. In some embodiments, the ratio of the width N1 to width G1 can be selected to be lower than 0.2 but is greater than 0.15, such as when requirements of threshold voltage uniformity is more relaxed (e.g., sigma degradation only needs to be less than 10% instead of 5%) and when reducing effective capacitance is more critical.

Although not limiting, the present disclosure offers advantages for semiconductor devices having a gate isolation feature. One example advantage is forming an embedded air gap in the gate isolation feature to reduce gate-end to gate-end capacitive coupling. Another example advantage is incorporating barrier liners in the gate isolation feature to improve threshold voltage uniformity by preventing oxygen diffusion. Another example advantage is utilizing a backside air gap formation process to improve process window. Another example advantage is the freedom of using sacrificial layers substantially free of oxygen as part of forming the gate isolation feature. Another example advantage is the tuning of various gate isolation feature dimensions for optimal device performance.

One aspect of the present disclosure pertains to a method of forming a semiconductor device. The method includes forming first and second active regions over a substrate; forming a metal gate structure extending over the first and the second active regions; etching through the metal gate structure to form a trench between the first and the second active regions; depositing a barrier layer in the trench, the barrier layer conforms to and partially fills the trench; depositing a sacrificial layer over the barrier layer to fully fill the trench; planarizing top surfaces of the barrier layer and the sacrificial layer to form a gate isolation feature having the barrier layer and the sacrificial layer; thinning down the substrate and the gate isolation feature from a backside to form an opening in the barrier layer, the opening exposes a bottom surface of the sacrificial layer; removing the sacrificial layer through the opening to form a modified gate isolation feature, the modified gate isolation feature having an air gap between portions of the barrier layer; and forming a capping layer on the backside of the modified gate isolation feature to seal the air gap.

In an embodiment, the barrier layer includes silicon nitride and the sacrificial layer includes silicon oxide. In a further embodiment, the removing of the sacrificial layer includes applying an etchant that selectively etches silicon oxide at a faster rate than silicon nitride.

In an embodiment, the sacrificial layer includes a bottom anti-reflective coating (BARC) layer.

In an embodiment, the thinning down of the substrate forms a thinned-down semiconductor workpiece, where the removing of the sacrificial layer includes: forming a hard mask on the backside of the thinned-down semiconductor workpiece; patterning the hard mask to form a hard mask opening exposing the sacrificial layer of the gate isolation feature; etching the sacrificial layer through the hard mask opening; and removing the patterned hard mask. In an embodiment, the hard mask opening also exposes bottom surfaces of the barrier layer, and the etching of the sacrificial layer partially etches bottom portions of the barrier layer.

In an embodiment, the method further includes forming one or more dielectric layers over the metal gate structure, where the etching through the metal gate structure further includes etching through the one or more dielectric layers.

In an embodiment, the method further includes forming a frontside interconnect structure over the gate isolation feature before the thinning down of the substrate.

In an embodiment, the method further includes forming an isolation structure over the substrate, where the first and the second active regions include bottom portions surrounded by the isolation structure and top portions protruding above the isolation structure. The etching through the metal gate structure further includes etching through the isolation structure to expose a top surface of the substrate. In a further embodiment, the thinning down of the substrate includes thinning down the first and the second active regions from the backside to expose a bottom surface of the isolation structure.

In an embodiment, the capping layer includes a portion that dips into the opening.

Another aspect of the present disclosure pertains to a method of forming a semiconductor device. The method includes forming first and second active regions protruding from a substrate; forming an isolation structure over the substrate and between the first and the second active regions; forming S/D features in S/D regions of the first and the second active regions; forming semiconductor channels in channel regions of the first and the second active regions; forming a metal gate structure wrapping around the semiconductor channels in each of the first and the second active regions; etching through the metal gate structure and the isolation structure to form a trench between the first and the second active regions and exposing a top surface of the substrate; forming a gate isolation feature in the trench; forming an interconnect structure over the gate isolation feature; thinning down the substrate from a backside to remove the substrate and to expose bottom surfaces of the isolation structure, the first and the second active regions, and the gate isolation feature; selectively etching the gate isolation feature to form a modified gate isolation feature having an air gap; and depositing a capping layer on the exposed bottom surfaces of the isolation structure, the first and the second active regions, and the modified gate isolation feature to seal the air gap.

In an embodiment, the gate isolation feature includes a barrier layer surrounding a sacrificial fill layer, and the selectively etching of the gate isolation feature selectively removes the sacrificial fill layer.

In an embodiment, the air gap exposes a bottom surface of the interconnect structure, a top surface of the capping layer, and side surfaces of a barrier layer of the modified gate isolation feature.

In an embodiment, the method further includes forming one or more interlayer dielectric (ILD) layers over the metal gate structure; and forming S/D contacts in the one or more ILD layers and contacting the S/D features. The etching through the metal gate structure and the isolation structure further includes etching through the one or more ILD layers.

Another aspect of the present disclosure pertains to a semiconductor device. The semiconductor device includes a first stack of semiconductor channels disposed over a first active region; a second stack of semiconductor channels disposed over a second active region; an isolation structure surrounding the first and the second active regions; a metal gate structure over the isolation structure and wrapping around each semiconductor channel in the first and the second stacks of semiconductor channels; a gate isolation feature cutting through and separating the metal gate structure into two segments, the gate isolation feature includes an air gap between barrier liners; an interconnect structure over the gate isolation feature; and a capping layer under the gate isolation feature.

In an embodiment, the barrier liners directly interface side surfaces of the metal gate.

In an embodiment, the air gap is defined by exposed surfaces of the interconnect structure, the barrier liners, and the capping layer.

In an embodiment, the capping layer lands on a bottom surface of the isolation structure, the first active region, the second active region, and the barrier liners.

In an embodiment, the gate isolation feature has a first width, the air gap has a second width, and the barrier liners have a third width defined as a difference between the first width and the second width, where a ratio of the third width to the first width ranges between about 0.2 to about 0.5.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method of forming a semiconductor device, comprising:
forming first and second active regions over a substrate;
forming a metal gate structure extending over the first and the second active regions;
etching through the metal gate structure to form a trench between the first and the second active regions;
depositing a barrier layer in the trench, the barrier layer conforms to and partially fills the trench;
depositing a sacrificial layer over the barrier layer to fully fill the trench;
planarizing top surfaces of the barrier layer and the sacrificial layer to form a gate isolation feature having the barrier layer and the sacrificial layer;
thinning down the substrate and the gate isolation feature from a backside to form an opening in the barrier layer, the opening exposes a bottom surface of the sacrificial layer;
removing the sacrificial layer through the opening to form a modified gate isolation feature, the modified gate isolation feature having an air gap between portions of the barrier layer; and
forming a capping layer on the backside of the modified gate isolation feature to seal the air gap.

2. The method of claim 1, wherein the barrier layer includes silicon nitride and the sacrificial layer includes silicon oxide.

3. The method of claim 2, wherein the removing of the sacrificial layer includes applying an etchant that selectively etches silicon oxide at a faster rate than silicon nitride.

4. The method of claim 1, wherein the sacrificial layer includes a bottom anti-reflective coating (BARC) layer.

5. The method of claim 1, wherein the thinning down of the substrate forms a thinned-down semiconductor workpiece, wherein the removing of the sacrificial layer includes:
forming a hard mask on the backside of the thinned-down semiconductor workpiece;
patterning the hard mask to form a hard mask opening exposing the sacrificial layer of the gate isolation feature;
etching the sacrificial layer through the hard mask opening; and
removing the patterned hard mask.

6. The method of claim 5, wherein the hard mask opening also exposes bottom surfaces of the barrier layer, and the etching of the sacrificial layer partially etches bottom portions of the barrier layer.

7. The method of claim 1, further comprising:
forming one or more dielectric layers over the metal gate structure, wherein the etching through the metal gate structure further includes etching through the one or more dielectric layers.

8. The method of claim 1, further comprising:
forming a frontside interconnect structure over the gate isolation feature before the thinning down of the substrate.

9. The method of claim 1, further comprising:
forming an isolation structure over the substrate, wherein the first and the second active regions include bottom portions surrounded by the isolation structure and top portions protruding above the isolation structure,
wherein the etching through the metal gate structure further includes etching through the isolation structure to expose a top surface of the substrate.

10. The method of claim 9, wherein the thinning down of the substrate includes thinning down the first and the second active regions from the backside to expose a bottom surface of the isolation structure.

11. The method of claim 1, wherein the capping layer includes a portion that dips into the opening.

12. A method of forming a semiconductor device, comprising:
forming first and second active regions protruding from a substrate;
forming an isolation structure over the substrate and between the first and the second active regions;
forming S/D features in S/D regions of the first and the second active regions;
forming semiconductor channels in channel regions of the first and the second active regions;
forming a metal gate structure wrapping around the semiconductor channels in each of the first and the second active regions;
etching through the metal gate structure and the isolation structure to form a trench between the first and the second active regions and exposing a top surface of the substrate;
forming a gate isolation feature in the trench;
forming an interconnect structure over the gate isolation feature;
thinning down the substrate from a backside to remove the substrate and to expose bottom surfaces of the isolation structure, the first and the second active regions, and the gate isolation feature;
selectively etching the gate isolation feature to form a modified gate isolation feature having an air gap; and
depositing a capping layer on the exposed bottom surfaces of the isolation structure, the first and the second active regions, and the modified gate isolation feature to seal the air gap.

13. The method of claim 12, wherein the gate isolation feature includes a barrier layer surrounding a sacrificial fill layer, and the selectively etching of the gate isolation feature selectively removes the sacrificial fill layer.

14. The method of claim 12, wherein the air gap exposes a bottom surface of the interconnect structure, a top surface of the capping layer, and side surfaces of a barrier layer of the modified gate isolation feature.

15. The method of claim 12, further comprising:
forming one or more interlayer dielectric (ILD) layers over the metal gate structure; and
forming S/D contacts in the one or more ILD layers and contacting the S/D features,
wherein the etching through the metal gate structure and the isolation structure further includes etching through the one or more ILD layers.

16. A semiconductor device, comprising:
a first stack of semiconductor channels disposed over a first active region;
a second stack of semiconductor channels disposed over a second active region;
an isolation structure surrounding the first and the second active regions;
a metal gate structure over the isolation structure and wrapping around each semiconductor channel in the first and the second stacks of semiconductor channels;
a gate isolation feature cutting through and separating the metal gate structure into two segments, the gate isolation feature includes an air gap between barrier liners;
an interconnect structure over the gate isolation feature; and
a capping layer under the gate isolation feature.

17. The semiconductor device of claim 16, wherein the barrier liners directly interface side surfaces of the metal gate.

18. The semiconductor device of claim 16, wherein the air gap is defined by exposed surfaces of the interconnect structure, the barrier liners, and the capping layer.

19. The semiconductor device of claim 16, wherein the capping layer lands on a bottom surface of the isolation structure, the first active region, the second active region, and the barrier liners.

20. The semiconductor device of claim 16,
wherein the gate isolation feature has a first width, the air gap has a second width, and the barrier liners have a third width defined as a difference between the first width and the second width,
wherein a ratio of the third width to the first width ranges between about 0.2 to about 0.5.
